(19) United States
(12) Patent Application Publication
(10) Pub. No.: US 2013/0201669 A1
(43) Pub. Date: Aug. 8, 2013

(54) LED ILLUMINATION APPARATUS WITH IMPROVED OUTPUT UNIFORMITY

(71) Applicants: Wei-Yu Yeh, Tainan City (TW); Pei-Wen Ko, Zhubei City (TW)

(72) Inventors: Wei-Yu Yeh, Tainan City (TW); Pei-Wen Ko, Zhubei City (TW)

(73) Assignee: TAIWAN SEMICONDUCTOR MANUFACTURING COMPANY, LTD, Hsin-Chu (TW)

(21) Appl. No.: 13/366,063

(22) Filed: Feb. 3, 2012

(51) Int. Cl. F21L 4/02; F21V 21/00; H01L 33/58; F21V 5/04

(52) U.S. Cl. 362/184; 362/235; 362/249.02; 438/27; 257/E33.056

(57) ABSTRACT

The present disclosure involves an LED illumination apparatus. The illumination apparatus includes a substrate and a plurality of LED modules disposed over the substrate according to a predefined layout pattern. The layout pattern includes a row having a vertically-aligned LED module located laterally adjacent to a first horizontally-aligned LED module and a second horizontally-aligned LED module. The layout pattern also includes a column having a horizontally-aligned LED module located laterally adjacent to a first vertically-aligned LED module and a second vertically-aligned LED module. The layout pattern further includes a row of horizontally-aligned LED modules located laterally adjacent to one another. The illumination apparatus also includes a diffuser disposed over the plurality of LED modules. Each LED module also includes a secondary optical component providing an asymmetric light pattern. The plurality of LED modules provides a linear light distribution or a planar light distribution on the diffuser.

### TECHNICAL FIELD

The present disclosure relates generally to light-emitting devices, and more particularly, to a cost-effective light-emitting diode (LED) lighting instrument having improved light output uniformity.

### BACKGROUND

An LED device, as used herein, is a semiconductor light source for generating a light at a specified wavelength or a range of wavelengths. LED devices emit light when a voltage is applied. LED devices have increasingly gained popularity due to favorable characteristics such as small device size, long lifetime, efficient energy consumption, and good durability and reliability. In recent years, LED devices have been deployed in various applications, including indicators, light sensors, traffic lights, broadband data transmission, and illumination apparatuses. For example, LED devices are often used in illumination apparatuses provided to replace conventional incandescent light bulbs, such as those used in a troffer light.

One of the performance criteria for LED illumination apparatuses is light output uniformity. For example, it is desired that the light output for an LED illumination apparatus maintain relatively uniform color and brightness throughout different areas of the LED illumination apparatus. However, existing LED illumination apparatuses often suffer from poor light output uniformity. For example, the number of discrete LED devices used in a conventional LED illumination apparatus may lead to light output hot spots. In other words, existing LED illumination apparatuses may produce a light output that is not uniform but includes a plurality of intensely lit regions surrounded by dimmer regions, which may cause discomfort (e.g., glare) for a human eye and is therefore undesirable. Existing methods of addressing these issues may lead to expensive fabrication costs and/or longer fabrication time.

Therefore, while conventional LED illumination apparatuses have been generally adequate for their intended purposes, they have not been entirely satisfactory in every aspect. It is desired to provide an LED illumination apparatus that is free of hot spots and that distributes light in more uniform fashion across all directions, similar to that of an incandescent light bulb.

### BRIEF DESCRIPTION OF THE DRAWINGS

Aspects of the present disclosure are understood from the following detailed description when read with the accompanying figures. It is emphasized that, in accordance with the standard practice in the industry, various features may not be drawn to scale. In fact, the dimensions of the various features may be arbitrarily increased or reduced for clarity of discussion.

FIG. 1 is a flowchart of a method of fabricating an LED illumination apparatus in accordance with embodiments of the present disclosure.

FIG. 2 is a bottom view of an LED illumination apparatus without a diffuser in accordance with embodiments of the present disclosure, and FIGS. 2A-2D are cross-sectional views of the LED illumination apparatus of FIG. 2 including a diffuser in accordance with embodiments of the present disclosure.

FIG. 3 is a bottom view of an LED illumination apparatus including a diffuser and a corresponding light distribution on the diffuser in accordance with embodiments of the present disclosure.

FIG. 4 illustrates an asymmetric light pattern of an LED module in accordance with embodiments of the present disclosure.

FIG. 5 illustrates a top view of an LED illumination apparatus with a plurality of LEDs having interleaving light patterns according to various aspects of the present disclosure.

FIG. 6 is a diagrammatic view of a lighting module that includes an LED lighting apparatus according to various aspects of the present disclosure.

### DETAILED DESCRIPTION

It is understood that the following disclosure provides many different embodiments, or examples, for implementing different features of the disclosure. Specific examples of components and arrangements are described below to simplify the present disclosure. These are, of course, merely examples and are not intended to be limiting. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for the sake of simplicity and clarity. It is noted that the same or similar features may be similarly numbered herein for the sake of simplicity and clarity. In addition, some of the drawings may be simplified for clarity. Thus, the drawings may not depict all of the components of a given apparatus (e.g., device) or method.

When turned on, light-emitting diode (LED) devices may emit radiation such as different colors of light in a visible spectrum, as well as radiation with ultraviolet or infrared wavelengths. Compared to traditional light sources (e.g., incandescent light bulbs), LED devices offer advantages such as smaller size, lower energy consumption, longer lifetime, variety of available colors, and greater durability and reliability. These advantages, as well as advancements in LED fabrication technologies that have made LED devices cheaper and more robust, have added to the growing popularity of LED devices in recent years.

Some of the LED-based applications include LED illumination apparatuses, for example, LED lamps. These LED illumination apparatuses are capable of replacing traditional illumination apparatuses (such as incandescent light bulbs) in many aspects. However, existing LED illumination apparatuses such as LED troffer lights may suffer from drawbacks involving non-uniform light distribution intensity (or luminous intensity or lumen density). For example, existing LED illumination apparatuses troffer lights may have a substantially greater light intensity at the center of its output (i.e., the front direction along which light is projected). As another example, existing LED illumination apparatuses typically employ a plurality of discrete LED devices (e.g., LED emitters) that may cause the collective light output to contain a plurality of brighter spots surrounded by dimmer regions, which is otherwise known as a hot spot phenomenon. Due at least in part to these unfavorable light output characteristics, it is difficult for existing LED illumination apparatuses to conform to the light distribution patterns of incandescent illumination apparatuses.

Some existing methods have attempted to address these issues by implementing a greater number of LED emitters on the same plane for a given illumination apparatus, and/or by adding a diffuser to make the light distribution pattern smoother. However, these approaches are not only expensive (as they require more LED emitters or additional components) to implement, but they also lead to degraded performance since the diffuser generally has poor transparency and as such reduces the efficiency of the light output. Therefore, an inexpensive method to overcome the light output uniformity issues for existing LED illumination apparatuses is needed.

According to various aspects of the present disclosure, described below is a cost-effective approach to improve the light output uniformity of LED illumination apparatuses without performance degradations.

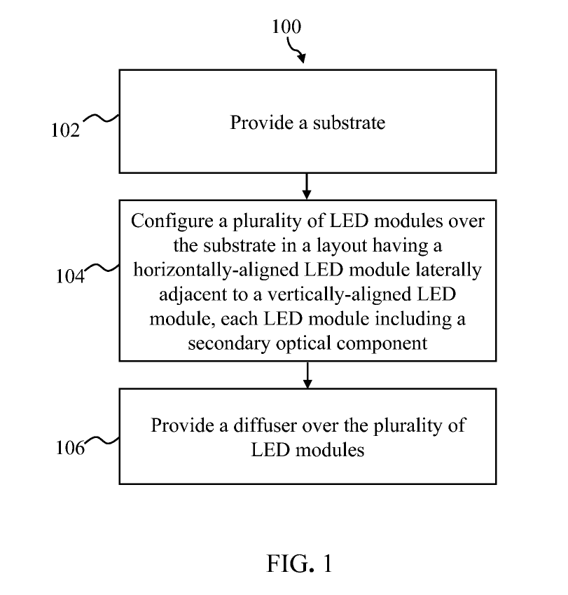

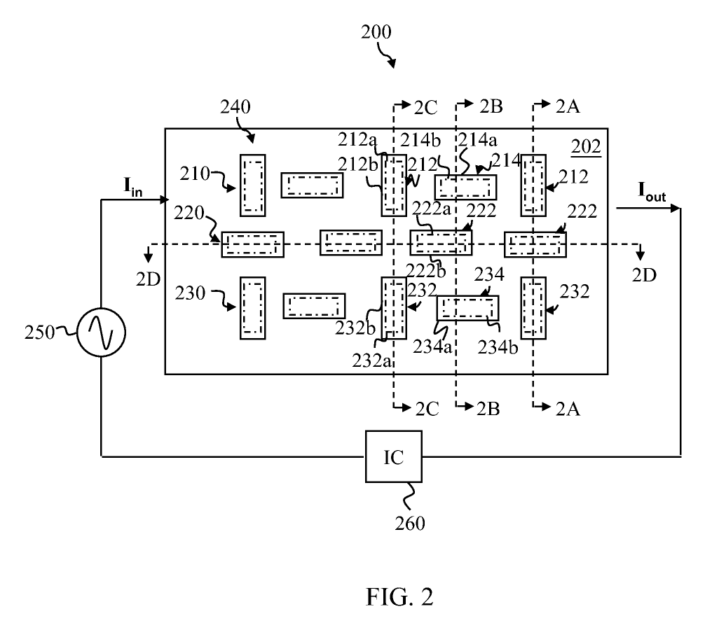

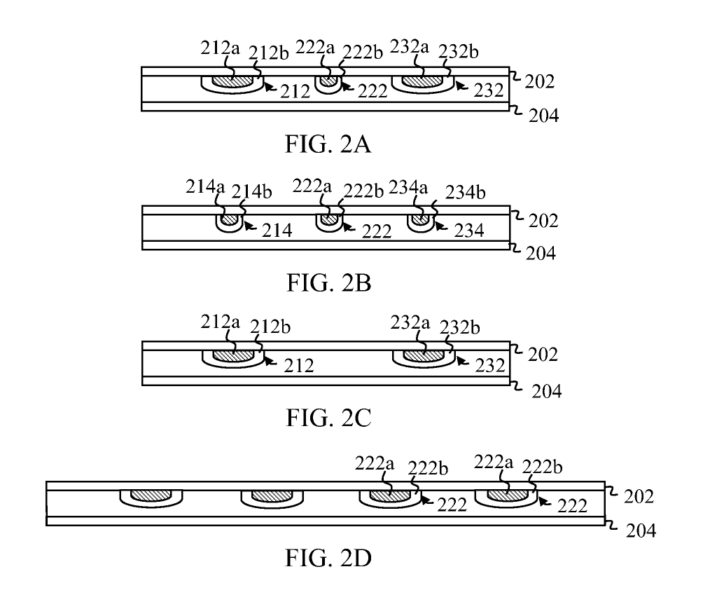

Referring now to FIG. 1, a flowchart is shown illustrating a method 100 for fabricating an LED illumination apparatus in accordance with embodiments of the present disclosure. Method 100 includes providing a substrate at block 102, and configuring a plurality of LED modules over the substrate in a layout at block 104. The LED modules may be oblong rectangles or other shapes having one axis (x or y) longer than the other (y or x), for example, an oval. According to various aspects of the present disclosure, reference to vertically-aligned LED modules or horizontally-aligned LED modules throughout this document will refer to LED modules that have a lengthwise-axis (longer side) that is aligned with the y- or x-axes, respectively, of the top plane of the substrate. An example of a horizontally-aligned LED module having a lengthwise axis aligned with the x-axis of the substrate plane is shown by LED modules 214, 222, and 234 in FIG. 2, and an example of a vertically-aligned LED module having a lengthwise axis aligned with the y-axis of the substrate plane is shown by LED modules 212 and 232 in FIG. 2. The layout of the LED modules on the substrate includes a horizontally-aligned LED module laterally adjacent to a vertically-aligned LED module. Method 100 further includes providing a diffuser over the plurality of LED modules at block 106.

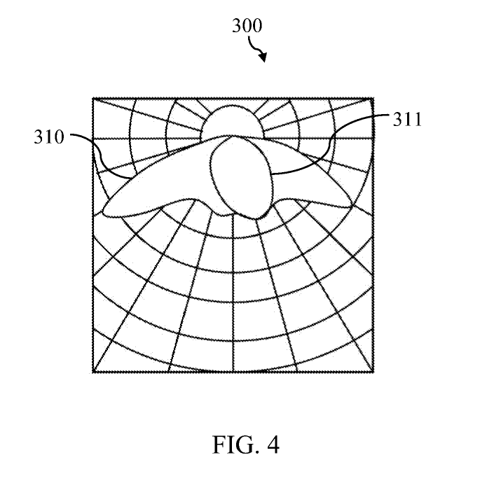

According to one aspect, each LED module includes a secondary optical component over an LED to provide an asymmetric light pattern. In one example, an LED module includes an LED die operably coupled to a secondary optical component, such as a lens, that provides an asymmetric light pattern, which is a light pattern not symmetric in all directions, an example of which is shown in FIG. 4 as being a “lambertian” pattern 310 (or a pseudo-lambertian pattern) and a “bat-wing” pattern 311. In some embodiments, the secondary optical component changes the LED die “pseudo-lambertian” light pattern to a “bat-wing” light pattern. For example, the secondary optical component may provide a “pseudo-lambertian” light pattern on a Y-Z plane and a “bat-wing” light pattern on a X-Z plane. In other embodiments, the asymmetric light pattern pertains to the fact that some LED modules may direct light at a different angle than other LED modules.

In some embodiments, for each row of LED dies and each column of LED dies, the pseudo-lambertian light patterns are interleaved with the bat-wing patterns. This may be done either by installing lenses different on a square LED, or by installing square LEDs at 90 degrees on the same package to the same effect as using oblong LEDs. In various embodiments, the vertical and horizontal alignment discussed herein are defined in accordance with the different types of light patterns. For example, vertical may refer to a particular light pattern A (e.g., a pseudo-lambertian pattern) on a YZ plane, and horizontal may refer to a different light pattern B (e.g., a bat-wing pattern) different from the pattern A on an XZ plane. The light patterns A and B may include patterns other than the pseudo-lambertian and bat-wing patterns. The asymmetric light pattern is discussed in detail below.

The various structures in method 100 described above may be formed by various techniques, such as deposition, patterning, and/or etching techniques. It should be noted that the operations of method 100 may be rearranged or otherwise modified within the scope of the various aspects. It is further noted that additional processes may be provided before, during, and after the operations of method 100, and that some other processes may only be briefly described herein. Thus, other implementations are possible within the scope of the various aspects described herein.

According to an aspect of the present disclosure, the plurality of LED modules may be configured over the substrate to include a row having a vertically-aligned LED module laterally adjacent to a first horizontally-aligned LED module and a second horizontally-aligned LED module.

According to another aspect of the present disclosure, the plurality of LED modules may be configured over the substrate to include a row having a horizontally-aligned LED module laterally adjacent to a first vertically-aligned LED module and a second vertically-aligned LED module.

According to yet another aspect of the present disclosure, the plurality of LED modules may be configured over the substrate to include a row of horizontally-aligned LED modules laterally adjacent to one another.

According to yet another aspect of the present disclosure, the plurality of LED modules may be configured over the substrate to include a column having a horizontally-aligned LED module laterally adjacent to a first vertically-aligned LED module and a second vertically-aligned LED module.

According to yet another aspect of the present disclosure, the plurality of LED modules may be coupled in series and/or in parallel in accordance with various embodiments of the present disclosure.

Advantageously, the plurality of LED modules providing asymmetric light patterns and disposed in a layout as described above can provide a linear light distribution and/or a planar light distribution on the diffuser to provide a linear and/or planar light source.

Referring now to FIGS. 2 and 2A-2D, FIG. 2 illustrates a bottom view of an LED illumination apparatus 200 without a diffuser in accordance with embodiments of the present disclosure, and FIGS. 2A-2D illustrate various cross-sectional views of the LED illumination apparatus 200 including a diffuser along lines 2A-2A, 2B-2B, 2C-2C, and 2D-2D, respectively, in accordance with embodiments of the present disclosure.

In accordance with an embodiment of the present disclosure, the LED illumination apparatus 200 includes a substrate 202, and a plurality of LED modules (e.g., LED modules 212, 214, 222, 232, 234) disposed thereon. In some embodiments, the substrate 202 includes a Metal Core Printed Circuit Board (MCPCB). The MCPCB includes a metal base that may be made of Aluminum (or an alloy thereof). The MCPCB also includes a thermally conductive but electrically insulating dielectric layer disposed on the metal base. The MCPCB may also include a thin metal layer made of copper that is disposed on the dielectric layer. In certain embodiments, the substrate 202 may include other suitable thermally conductive structures, such as ceramic. The substrate 202 may contain active circuitry and may also be used to establish interconnections.

These LED modules function as light sources for the LED illumination apparatus 200. Each LED module includes an LED emitter or LED die. In certain embodiments, each LED module includes an LED die itself as well as the gel covering the die. Each LED die includes two oppositely doped semiconductor layers. In some embodiments, the oppositely doped semiconductor layers each contain a “III-V” family (or group) compound. In more detail, a III-V family compound contains an element from a “III” family of the periodic table, and another element from a “V” family of the periodic table. For example, the III family elements may include Boron, Aluminum, Gallium, Indium, and Titanium, and the V family elements may include Nitrogen, Phosphorous, Arsenic, Antimony, and Bismuth. In certain embodiments, the oppositely doped semiconductor layers include a p-doped gallium nitride (GaN) material and an n-doped gallium nitride material, respectively. The p-type dopant may include Magnesium (Mg), and the n-type dopant may include Carbon (C) or Silicon (Si).

Each LED die also includes a multiple-quantum well (MQW) layer that is disposed in between the oppositely doped layers. The MQW layer includes alternating (or periodic) layers of active material, such as gallium nitride and indium gallium nitride (InGaN). For example, the MQW layer may include a number of gallium nitride layers and a number of indium gallium nitride layers, wherein the gallium nitride layers and the indium gallium nitride layers are formed in an alternating or periodic manner. In some embodiments, the MQW layer includes ten layers of gallium nitride and ten layers of indium gallium nitride, where an indium gallium nitride layer is formed on a gallium nitride layer, and another gallium nitride layer is formed on the indium gallium nitride layer, and so on and so forth. The light emission efficiency depends on the number of layers of alternating layers and thicknesses.

In various embodiments, each LED die may also include a pre-strained layer and an electron-blocking layer. The pre-strained layer may be doped and may serve to release strain and reduce a Quantum-Confined Stark Effect (QCSE)—describing the effect of an external electric field upon the light absorption spectrum of a quantum well—in the MQW layer. The electron blocking layer may include a doped aluminum gallium nitride (AlGaN) material, wherein the dopant may include Magnesium. The electron blocking layer helps confine electron-hole carrier recombination to within the MQW layer, which may improve the quantum efficiency of the MQW layer and reduce radiation in undesired bandwidths.

The doped layers and the MQW layer may all be formed by one or more epitaxial growth processes known in the art. After the completion of the epitaxial growth process, an LED is created by the disposition of the MQW layer between the doped layers. When an electrical voltage (or electrical charge) is applied to the doped layers of the LED, the MQW layer emits radiation such as light. The color of the light emitted by the MQW layer corresponds to the wavelength of the radiation. The radiation may be visible, such as blue light, or invisible, such as ultraviolet (UV) light. The wavelength of the light (and hence the color of the light) may be tuned by varying the composition and structure of the materials that make up the MQW layer. Each LED die may also include electrodes or contacts that allow the LED die to be electrically coupled to external devices.

In the embodiment shown in FIG. 2, the plurality of LED modules are disposed over the substrate 202 in a layout configuration where a horizontally-aligned LED module (e.g., horizontally-aligned LED module 214 or 234) is disposed laterally adjacent to a vertically-aligned LED module (e.g., vertically-aligned LED module 212 or 232, respectively). According to one aspect, each LED module includes an LED die and a secondary optical component (e.g., LED module 212 includes an LED die 212a and a secondary optical component 212b, LED module 214 includes an LED die 214a and a secondary optical component 214b, LED module 222 includes an LED die 222a and a secondary optical component 222b, LED module 232 includes an LED die 232a and a secondary optical component 232b, and LED module 234 includes an LED die 234a and a secondary optical component 234b). The illumination apparatus 200 further includes a diffuser 204 disposed over the plurality of LED modules.

In one example, the secondary optical component, such as a lens, provides an asymmetric light pattern on the diffuser, which is a light pattern not symmetric in all directions, an example of which is shown in FIG. 4. In some embodiments, the secondary optical component changes the LED die's light output pattern from a “lambertian” light pattern to a “bat-wing” light pattern. For example, the secondary optical component may provide a “lambertian” light pattern on a Y-Z plane and a “bat-wing” light pattern on a X-Z plane. In yet another example, some LED modules may direct light at a different angle than other LED modules.

In accordance with various embodiments of the present disclosure, the layout of the plurality of LED modules may include rows and columns of LED modules aligned lengthwise in a horizontal or vertical direction along the plane of the substrate 202. In one embodiment, adjacent light modules may have different orientations. Advantageously, the layout of the plurality of LED modules may form a patterned array of LED modules to provide a linear and/or planar light distribution with substantially reduced glare.

In accordance with certain aspects of the present disclosure, the layout of the plurality of LED modules in the illumination apparatus 200 may include a row having a vertically-aligned LED module laterally adjacent to a first horizontally-aligned LED module and a second horizontally-aligned LED module. For example, rows 210 or 230 each have vertically-aligned LED module 212 or 232 disposed between horizontally-aligned LED module 214 or 234, respectively. Row 210 is comprised of vertically-aligned LED modules 212 between horizontally-aligned LED modules 214, and row 230 is comprised of vertically-aligned LED modules 232 between horizontally-aligned LED modules 234.

In accordance with another aspect of the present disclosure, the layout of the plurality of LED modules in the illumination apparatus 200 includes a row having a horizontally-aligned LED module laterally adjacent to a first vertically-aligned LED module and a second vertically-aligned LED module. For example, each of rows 210 or 230 have horizontally-aligned LED module 214 or 234 disposed between vertically-aligned LED module 212 or 232. Row 210 is comprised of horizontally-aligned LED modules 214 between vertically-aligned LED modules 212, and row 230 is comprised of horizontally-aligned LED modules 234 between vertically-aligned LED modules 232.

In accordance with another aspect of the present disclosure, the layout of the plurality of LED modules in the illumination apparatus 200 includes a row of horizontally-aligned LED modules laterally adjacent to one another. For example, row 220 is comprised of horizontally-aligned LED modules 222 adjacent to one another.

In accordance with another aspect of the present disclosure, the layout of the plurality of LED modules in the illumination apparatus 200 includes a column (e.g., column 240) having a horizontally-aligned LED module laterally adjacent to a first vertically-aligned LED module and a second vertically-aligned LED module (e.g., horizontally-aligned LED module 222 disposed between vertically-aligned LED modules 212 and 232). In one example, column 240 is comprised of LED modules 222 disposed between LED modules 212 and 232.

In accordance with yet another aspect of the present disclosure, the plurality of LED modules of the illumination apparatus 200 may be coupled in series and/or in parallel with one another, or portions of the plurality of LED modules may be coupled in series and/or in parallel.

In accordance with yet another aspect of the present disclosure, the illumination apparatus 200 is coupled to a power source 250 for providing current to the plurality of LED modules. The power source 250 is configured to provide an input current or a plurality of input currents Iᵢₙ to the plurality of LED modules. An output current or a plurality of output currents Iₒᵤₜ is provided out of the illumination apparatus 200. In accordance with one aspect, power source 250 provides DC power in one example, but may include any of various power supplies for providing current and/or voltage. In one example, power source 250 may convert AC power to stepping DC power. In another example, power source 250 may further include a power supply regulator and/or a diode bridge, and may provide a plurality of currents to the LED illumination apparatus 200.

In accordance with yet another aspect of the present disclosure, the illumination apparatus 200 may optionally include or be coupled to an integrated circuit (IC) 260 coupled to the power source 250 to control power delivery to the plurality of LED modules of the illumination apparatus 200, for example to dynamically power each of the plurality of LED modules or in some other way control power delivery to the plurality of LED modules. In another example, a plurality of currents may be delivered to different portions of the plurality of LED modules. In yet another example, IC 260 is configured to control electrical connections (e.g., switches or multiplexers) between LED modules or sets of LED modules, and IC 260 may dynamically reconfigure the electrical connections between the plurality of LED modules or sets of LED modules. In other words, IC 260 may configure or reconfigure a coupling scheme of the plurality of LED modules. Examples of applicable electrical connections include but are not limited to 2-way switches, 3-way switches, transistors, and MEMS transistors. In accordance with yet another aspect, IC 260 may be disposed over the substrate 202, within the substrate 202, and/or on a separate printed circuit board (PCB). In one example, PCB may be exterior to substrate 202.

Although the illumination apparatus 200 is illustrated with a certain number of LED modules, various numbers of LED modules may be used in various numbers of rows or columns of LED modules. The illumination apparatus 200 may not be limited to a particular number of LED modules, columns, and/or rows of LED modules.

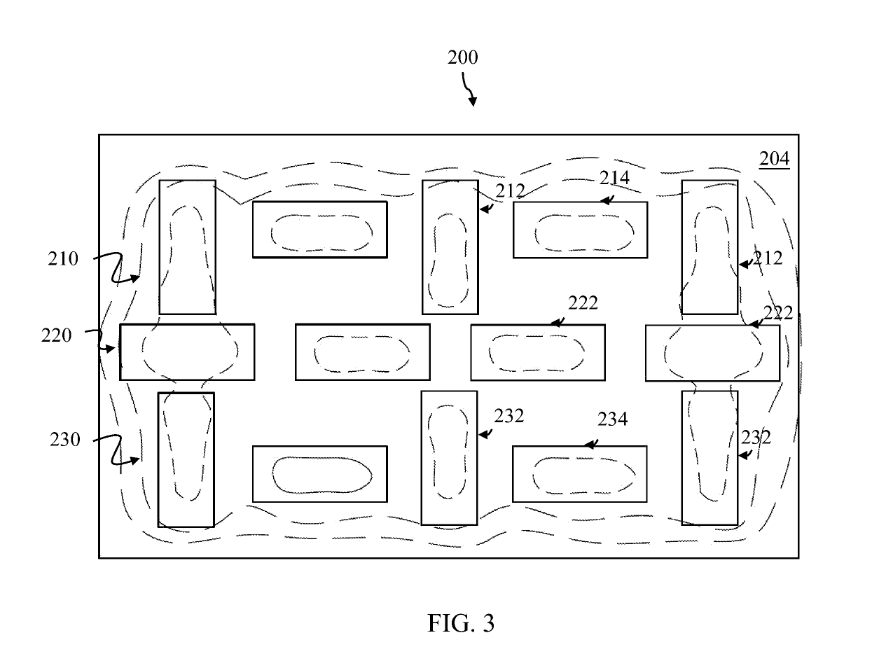

Referring now to FIGS. 3 and 4, FIG. 3 illustrates a bottom view of LED illumination apparatus 200 including a diffuser 204 and corresponding light distribution on the diffuser in accordance with embodiments of the present disclosure, and FIG. 4 illustrates an asymmetric light pattern 300 (including a pseudo-lambertian pattern 310 and a bat-wing pattern 311) of an LED module in accordance with embodiments of the present disclosure. The plurality of LED modules providing asymmetric light patterns (e.g., as shown in FIG. 4) and disposed in a layout as described above (e.g., as shown in FIGS. 2-2D) can provide a linear light distribution and/or a planar light distribution on the diffuser (e.g., as shown in FIG. 3) to provide a linear and/or planar light source.

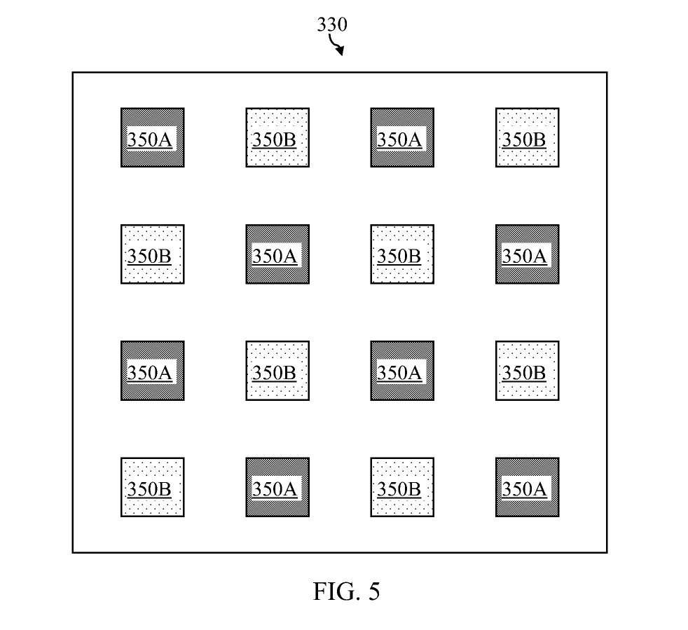

Referring now to FIG. 5, a diagrammatic top view of a substrate 330 containing a plurality of LED dies 350 is illustrated. The LED dies 350 are distributed two-dimensionally and form a plurality of rows (or columns). Within each row or column, each LED die may be disposed adjacently to another LED die outputting a different light pattern. In other words, LED dies 350A (having a light pattern A) interleave with the LED dies 350B (having a light pattern B). In some embodiments, the different light patterns A and B are pseudo-lambertian and bat-wing patterns, respectively. A particular light pattern can be achieved by installing different secondary lenses for the LED dies 350A and 350B, and/or by altering the lens orientations. For example, each pair of neighboring LED dies 350A and 350B may have different lens orientations.

In certain embodiments, two or more LED dies of the same light output pattern can be disposed adjacent to each other in certain areas. Stated differently, though LED dies having different light output patterns are interleaved with one another, the interleaving need not be on a one-to-one basis. For example, two LED dies associated with light out pattern A may be collectively interleaved with two LED dies associated with light out pattern B, forming an LED distribution pattern of A-A-B-B-A-A-B-B. In fact, the present disclosure allows for subsets of LED dies 350 to be distributed according to an ordered predefined pattern, where each subset of LED dies 350 may include one or more LED dies associated having the same light out pattern.

In further embodiments, the LED dies 350 may be distributed in a three-dimensional manner. For example, the LED dies 350 may be located on a surface that is not flat. Also, the predefined pattern of the LED dies 350 is not restricted to those shown in FIG. 5. Any other suitable pattern may be employed in different embodiments to satisfy design requirements and manufacturing concerns.

The present disclosure provides for a linear and/or planar light distribution from a unique layout of a plurality of LED modules, including vertically-aligned LED modules which are disposed laterally adjacent to horizontally-aligned LED modules. The present disclosure advantageously provides for a uniform light output with reduced glare using middle to high-power LEDs to provide a linear or planar light source that is easily installed and with lower cost.

Thus it can be seen that the LED illumination apparatus according to the embodiments disclosed herein offers advantages over existing LED illumination apparatuses. It is understood, however, that not all advantages are necessarily discussed herein, and different embodiments may offer additional advantages, and that no particular advantage is required for all embodiments.

One of the advantages is that the embodiments of the present disclosure are easy to implement. For example, the LED modules can be implemented according to the configuration discussed above with reference to FIG. 2 without requiring an additional fabrication process. Another advantage is that the embodiments of the present disclosure are cost-effective. For example, the embodiments of the present disclosure do not require a greater number of LED modules to improve light output uniformity. Instead, by configuration the layout and the orientation of each LED module carefully, the number of LED modules can be kept low or about the same as in other LED illumination apparatuses. The secondary lens for tuning the light output pattern into an asymmetric pattern is cheap too, and thus their implementation may have only a negligible impact on the overall cost of the illumination apparatus. Yet another advantage is that the uniformity for the collective light output of the illumination apparatus can be substantially improved. In other words, by arranging the LED modules in the predefined pattern and orientation, and by implementing a secondary lens that creates an asymmetric light output, the overall light output of the illumination apparatus can be substantially glare-free (and free of hot spots), thereby making it more friendly to the human eye.

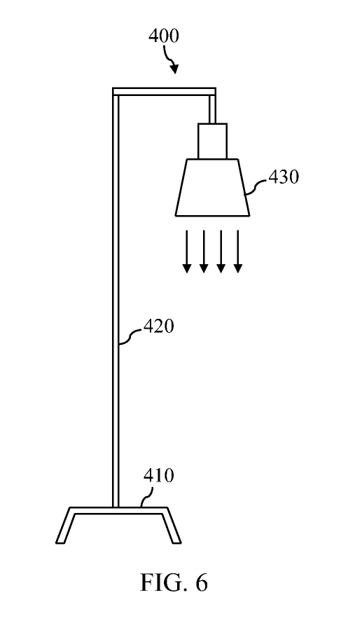

FIG. 6 illustrates a simplified diagrammatic view of a lighting module 400 that includes some embodiments of the illumination apparatus 200 discussed above. The lighting module 400 has a base 410, a body 420 attached to the base 410, and a lamp 430 attached to the body 420. In some embodiments, the lamp 430 is a down lamp (or a down light lighting module). In some embodiments, the lamp 430 is a troffer light.

The lamp 430 includes the illumination apparatus 200 discussed above with reference to FIGS. 1-4. In other words, the lamp 430 of the lighting module 400 includes an LED-based light source, wherein the LED dies are configured according to a predefined pattern. Due at least in part to the advantages discussed above, the LED illumination apparatus for the lamp 430 is operable to produce a uniform light output at a low cost compared to traditional LED lighting instruments.

Thus, the present disclosure provides for various embodiments. According to an embodiment, an LED illumination apparatus includes a substrate, and a plurality of LED modules disposed over the substrate in a layout having a horizontally-aligned LED module laterally adjacent to a vertically-aligned LED module. Each LED module includes a secondary optical component providing an asymmetric light pattern. The device further includes a diffuser disposed over the plurality of LED modules.

In another embodiment, an LED illumination apparatus includes a substrate, and a plurality of LED modules disposed over the substrate in a layout including: a row having a vertically-aligned LED module laterally adjacent to a first horizontally-aligned LED module and a second horizontally-aligned LED module; a column having a horizontally-aligned LED module laterally adjacent to a first vertically-aligned LED module and a second vertically-aligned LED module; and a row of horizontally-aligned LED modules laterally adjacent to one another. The LED illumination apparatus further includes a diffuser disposed over the plurality of LED modules, wherein each LED module includes a secondary optical component providing an asymmetric light pattern, and wherein the plurality of LED modules provides a linear light distribution or a planar light distribution on the diffuser.

In yet another embodiment, a method of fabricating an LED illumination apparatus includes providing a substrate, and configuring a plurality of LED modules over the substrate in a layout having a horizontally-aligned LED module laterally adjacent to a vertically-aligned LED module, wherein each LED module includes a secondary optical component providing an asymmetric light pattern. The method further includes providing a diffuser over the plurality of LED modules.

Although embodiments of the present disclosure have been described in detail, those skilled in the art should understand that they may make various changes, substitutions and alterations herein without departing from the spirit and scope of the present disclosure. Accordingly, all such changes, substitutions and alterations are intended to be included within the scope of the present disclosure as defined in the following claims. In the claims, means-plus-function clauses are intended to cover the structures described herein as performing the recited function and not only structural equivalents, but also equivalent structures.

What is claimed is:

1. A light-emitting diode (LED) illumination apparatus, comprising:
a substrate;
a plurality of LED modules disposed over the substrate in a layout having a horizontally-aligned LED module laterally adjacent to a vertically-aligned LED module, wherein each LED module includes a secondary optical component providing an asymmetric light pattern; and
a diffuser disposed over the plurality of LED modules.

2. The illumination apparatus of claim 1, wherein the plurality of LED modules are coupled in series and/or in parallel with one another.

3. The illumination apparatus of claim 1, wherein the layout of the plurality of LED modules includes a row having a vertically-aligned LED module laterally adjacent to a first horizontally-aligned LED module and a second horizontally-aligned LED module.

4. The illumination apparatus of claim 1, wherein the layout of the plurality of LED modules includes a row having a horizontally-aligned LED module laterally adjacent to a first vertically-aligned LED module and a second vertically-aligned LED module.

5. The illumination apparatus of claim 1, wherein the layout of the plurality of LED modules includes a row of horizontally-aligned LED modules laterally adjacent to one another.

6. The illumination apparatus of claim 1, wherein the layout of the plurality of LED modules includes a column having a horizontally-aligned LED module laterally adjacent to a first vertically-aligned LED module and a second vertically-aligned LED module.

7. The illumination apparatus of claim 1, wherein the secondary optical component is a lens.

8. The illumination apparatus of claim 1, further comprising an integrated circuit (IC) coupled to the plurality of LED modules, the IC adapted to dynamically power each of the plurality of LED modules.

9. The illumination apparatus of claim 8, further comprising a power source coupled to the plurality of LED modules and the IC, the power source configured to provide a plurality of currents to the plurality of LED modules.

10. A light-emitting diode (LED) illumination apparatus, comprising:
a substrate;
a plurality of LED modules disposed over the substrate in a layout including:
a row having a vertically-aligned LED module laterally adjacent to a first horizontally-aligned LED module and a second horizontally-aligned LED module;
a column having a horizontally-aligned LED module laterally adjacent to a first vertically-aligned LED module and a second vertically-aligned LED module; and
a row of horizontally-aligned LED modules laterally adjacent to one another; and
a diffuser disposed over the plurality of LED modules,
wherein each LED module includes a secondary optical component providing an asymmetric light pattern, and
wherein the plurality of LED modules provides a linear light distribution or a planar light distribution on the diffuser.

11. The illumination apparatus of claim 10, wherein the plurality of LED modules are coupled in series and/or in parallel with one another.

12. The illumination apparatus of claim 10, wherein the layout of the plurality of LED modules includes a row having a horizontally-aligned LED module laterally adjacent to a first vertically-aligned LED module and a second vertically-aligned LED module.

13. The illumination apparatus of claim 10, wherein the secondary optical component is a lens.

14. The illumination apparatus of claim 10, further comprising an integrated circuit (IC) coupled to the plurality of LED modules, the IC adapted to dynamically power each of the plurality of LED modules.

15. The illumination apparatus of claim 14, further comprising a power source coupled to the plurality of LED modules and the IC, the power source configured to provide a plurality of currents to the plurality of LED modules.

16. A method of fabricating a light-emitting diode (LED) illumination apparatus, the method comprising:
providing a substrate;
configuring a plurality of LED modules over the substrate in a layout having a horizontally-aligned LED module laterally adjacent to a vertically-aligned LED module, wherein each LED module includes a secondary optical component providing an asymmetric light pattern; and
providing a diffuser over the plurality of LED modules.

17. The method of claim 16, wherein the plurality of LED modules are configured over the substrate to include a row having a vertically-aligned LED module laterally adjacent to a first horizontally-aligned LED module and a second horizontally-aligned LED module.

18. The method of claim 16, wherein the plurality of LED modules are configured over the substrate to include a row having a horizontally-aligned LED module laterally adjacent to a first vertically-aligned LED module and a second vertically-aligned LED module.

19. The method of claim 16, wherein the plurality of LED modules are configured over the substrate to include a row of horizontally-aligned LED modules laterally adjacent to one another.

20. The method of claim 16, wherein the plurality of LED modules are configured over the substrate to include a column having a horizontally-aligned LED module laterally adjacent to a first vertically-aligned LED module and a second vertically-aligned LED module.
